(19) United States
(12) Patent Application Publication
(10) Pub. No.: US 2018/0019766 A1
(43) Pub. Date: Jan. 18, 2018

(54) PIPELINING FOR POLAR CODE LIST DECODING

(71) Applicant: QUALCOMM Incorporated, San Diego, CA (US)

(72) Inventors: Yang Yang, San Diego, CA (US); Jing Jiang, San Diego, CA (US); Jamie Menjay Lin, San Diego, CA (US); Hari Sankar, San Diego, CA (US); Joseph Binamira Soriaga, San Diego, CA (US)

(21) Appl. No.: 15/414,548

(22) Filed: Jan. 24, 2017

Related U.S. Application Data
(60) Provisional application No. 62/362,502, filed on Jul. 14, 2016.

(51) Int. Cl. H03M 13/39; H03M 13/13

(52) U.S. Cl. CPC H03M 13/3961; H03M 13/13

(57) ABSTRACT

Aspects of the present disclosure relate to pipelining two or more decoding stages during successive-cancellation polar code list decoding of a polar coded information transmission. During each cycle, the path metrics of candidate decoding paths of each of the pipelined decoding stages are compared and one of the candidate decoding paths from each pipelined decoding stage is selected for the next respective decoding stage.

### PRIORITY CLAIM

This application claims priority to and the benefit of Provisional Patent Application No. 62/362,502 filed in the U.S. Patent and Trademark Office on Jul. 14, 2016, the entire content of which is incorporated herein by reference as if fully set forth below in its entirety and for all applicable purposes.

### TECHNICAL FIELD

The technology discussed below relates generally to wireless communication systems, and more particularly, to polar code list decoding.

### BACKGROUND

Block codes, or error correcting codes are frequently used to provide reliable transmission of digital messages over noisy channels. In a typical block code, an information message or sequence is split up into blocks, and an encoder at the transmitting device then mathematically adds redundancy to the information message. Exploitation of this redundancy in the encoded information message is the key to reliability of the message, enabling correction for any bit errors that may occur due to the noise. That is, a decoder at the receiving device can take advantage of the redundancy to reliably recover the information message even though bit errors may occur, in part, due to the addition of noise to the channel.

Many examples of such error correcting block codes are known to those of ordinary skill in the art, including Hamming codes, Bose-Chaudhuri-Hocquenghem (BCH) codes, turbo codes, and low-density parity check (LDPC) codes, among others. Many existing wireless communication networks utilize such block codes, such as 3GPP LTE networks, which utilize turbo codes; and IEEE 802.11n Wi-Fi networks, which utilize LDPC codes. However, for future networks, a new category of block codes, called polar codes, presents a potential opportunity for reliable and efficient information transfer with improved performance relative to turbo codes and LDPC codes.

While research into implementation of polar codes continues to rapidly advance its capabilities and potential, additional enhancements are desired, particularly for potential deployment of future wireless communication networks beyond LTE.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Various aspects of the disclosure relate to mechanisms for pipelining two or more decoding stages during successive-cancellation polar code list decoding. During each cycle, successive-cancellation polar code list decoding may be performed by comparing path metrics of the candidate decoding paths of each of the pipelined decoding stages and selecting one of the candidate decoding paths from each pipelined decoding stage for the next respective decoding stage.

In one aspect of the disclosure, a method of pipelining polar code list decoding is disclosed. The method includes receiving a polar coded information transmission, and performing successive-cancellation list decoding of the polar coded information transmission. The successive-cancellation list decoding includes, during a cycle of a plurality of cycles, comparing respective first path metrics for each of a plurality of first candidate decoding paths of a first decoding stage and selecting one of the plurality of first candidate decoding paths for a second decoding stage following the first decoding stage, and comparing respective second path metrics for each of a plurality of second candidate decoding paths of the second decoding stage and selecting one of the plurality of second candidate decoding paths for a third decoding stage following the second decoding stage.

Another aspect of the disclosure provides an apparatus configured for pipelining polar code list decoding. The apparatus includes a transceiver, a memory, and a processor communicatively coupled to the transceiver and the memory. The processor is configured to receive a polar coded information transmission, and perform successive-cancellation list decoding of the polar coded information transmission. The successive-cancellation list decoding includes, during a cycle of a plurality of cycles, comparing respective first path metrics for each of a plurality of first candidate decoding paths of a first decoding stage and selecting one of the plurality of first candidate decoding paths for a second decoding stage following the first decoding stage, and comparing respective second path metrics for each of a plurality of second candidate decoding paths of the second decoding stage and selecting one of the plurality of second candidate decoding paths for a third decoding stage following the second decoding stage.

Another aspect of the disclosure provides an apparatus configured for pipelining polar code list decoding. The apparatus includes means for receiving a polar coded information transmission, and means for performing successive-cancellation list decoding of the polar coded information transmission. The means for performing successive-cancellation list decoding includes, during a cycle of a plurality of cycles, means for comparing respective first path metrics for each of a plurality of first candidate decoding paths of a first decoding stage and selecting one of the plurality of first candidate decoding paths for a second decoding stage following the first decoding stage, and means for comparing respective second path metrics for each of a plurality of second candidate decoding paths of the second decoding stage and selecting one of the plurality of second candidate decoding paths for a third decoding stage following the second decoding stage.

Examples of additional aspects of the disclosure follow. In some aspects of the disclosure, the method further includes, during the cycle, comparing respective third path metrics for each of a plurality of third candidate decoding paths of the third decoding stage and selecting one of the plurality of third candidate decoding paths as a selected decoding path for a fourth decoding stage following the third decoding stage. In some aspects of the disclosure, the method further includes, during the cycle, selecting an initial decoding path for the fourth decoding stage, in which the initial decoding path has a best path metric for the fourth decoding stage and the selected decoding path selected from the plurality of third candidate decoding paths has a second best path metric for the fourth decoding stage. In some aspects of the disclosure, the method further includes, during an immediately prior cycle, selecting the initial decoding path for the third decoding stage, where the initial decoding path is the same for each of a plurality of decoding stages including the first decoding stage, the second decoding stage, the third decoding stage and the fourth decoding stage.

In some aspects of the disclosure, the method further includes, during an initial cycle, selecting an initial decoding path for the second decoding stage, in which the initial decoding path having a best path metric for the second decoding stage, and comparing respective initial path metrics for each of a plurality of initial decoding paths of the first decoding stage and selecting one of the plurality of initial decoding paths as a second selected decoding path for the second decoding stage following the first decoding stage, where the second selected decoding path has a second best path metric for the second decoding stage. In some aspects of the disclosure, the method further includes utilizing unselected ones of the plurality of initial decoding paths in the plurality of first candidate decoding paths to select a third selected decoding path from the plurality of first candidate decoding paths for the second decoding stage, where the third selected decoding path has a third best path metric for the second decoding stage.

In some aspects of the disclosure, the method further includes, at each decoding stage of a plurality of decoding stages, splitting each of a plurality of current decoding paths into two additional decoding paths to produce a plurality of decoding paths, computing a respective path metric for each of the plurality of decoding paths, and selecting a subset of the plurality of decoding paths for a next decoding stage based on the respective path metrics of each of the plurality of decoding paths, where the subset of the plurality of decoding paths is selected based on a list size. In some aspects of the disclosure, the method further includes, at the first decoding stage of the plurality of decoding stages, selecting the subset of the plurality of decoding paths for the second decoding stage by selecting the plurality of first candidate decoding paths from the plurality of decoding paths, comparing the respective first path metrics for each of the plurality of first candidate decoding paths, and selecting one of the plurality of first candidate decoding paths for the second decoding stage based on the respective first path metrics.

In some aspects of the disclosure, the method further includes selecting at least two best candidates from unselected ones of the plurality of decoding paths as the plurality of first candidate decoding paths, where the at least two best candidates are predefined. In some aspects of the disclosure, the method further includes selecting the plurality of first candidate decoding paths based on previously selected decoding paths from a previous decoding stage during one or more previous cycles of the plurality of cycles, where the previous decoding stage is immediately prior to the first decoding stage. In some examples, the previously selected decoding paths have the best path metrics from the previous decoding stage.

In some aspects of the disclosure, the method further includes selecting the subset of the plurality of decoding paths in order of path metric ranking starting with a best path metric. In some aspects of the disclosure, the method further includes selecting a single most likely decoding path for the plurality of data bits by selecting one of the current decoding paths for a first one of the plurality of data bits, and selecting one of the subset of the plurality of decoding paths for a second one of the plurality of data bits.

These and other aspects of the invention will become more fully understood upon a review of the detailed description, which follows. Other aspects, features, and embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures below, all embodiments of the present invention can include one or more of the advantageous features discussed herein. In other words, while one or more embodiments may be discussed as having certain advantageous features, one or more of such features may also be used in accordance with the various embodiments of the invention discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 is a diagram illustrating an example of an access network.

FIG. 2 is a schematic illustration of wireless communication utilizing block codes.

FIG. 3 illustrates an example of polar code list decoding according to some embodiments.

FIG. 4 illustrates an example of decoding stages in polar code list decoding according to some embodiments.

FIG. 5 illustrates an example of decoding path selection in polar code list decoding according to some embodiments.

FIGS. 6-11 illustrate an example of pipelining decoding stages in polar code list decoding according to some embodiments.

FIG. 12 is a block diagram illustrating an example of a hardware implementation for a wireless communication device employing a processing system according to some embodiments.

FIG. 13 is a flow chart of a method for pipelining decoding stages in polar code list decoding according to some embodiments.

FIG. 14 is a flow chart of a method for performing successive-cancellation polar code list decoding according to some embodiments.

FIG. 15 is a flow chart of another method for performing successive-cancellation polar code list decoding according to some embodiments.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

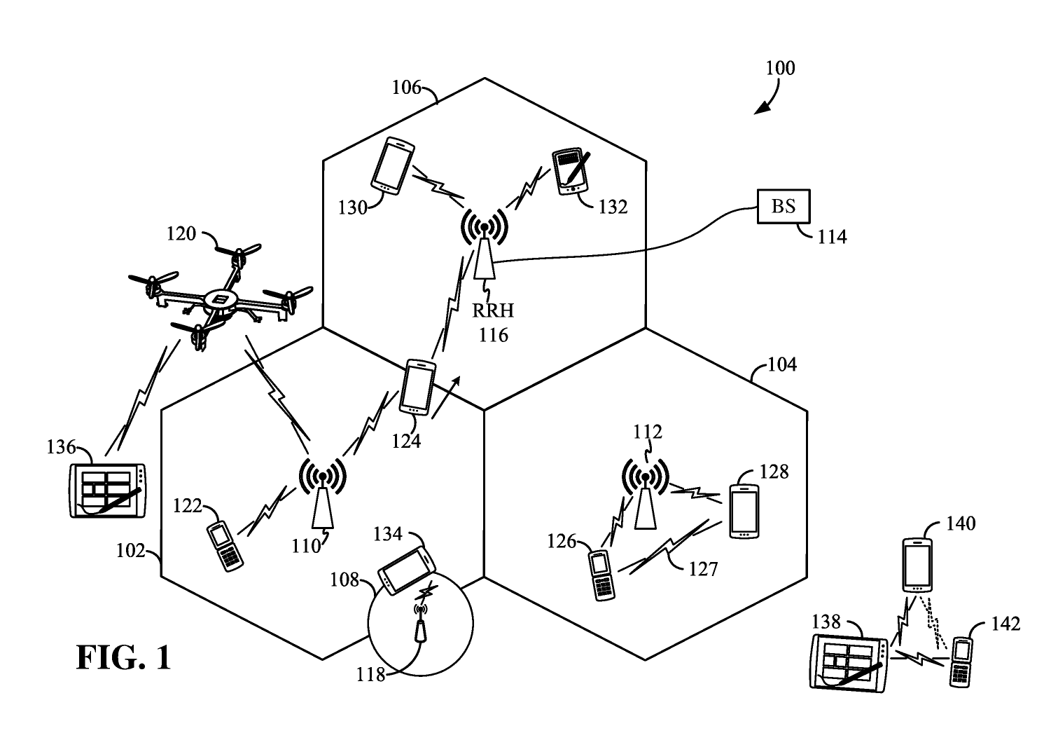

The various concepts presented throughout this disclosure may be implemented across a broad variety of telecommunication systems, network architectures, and communication standards. Referring now to FIG. 1, as an illustrative example without limitation, a simplified schematic illustration of an access network 100 is provided. The access network 100 may be a next generation (e.g., fifth generation (5G)) access network or a legacy (3G or 4G) access network. In addition, one or more nodes in the access network 100 may be next generation nodes or legacy nodes.

As used herein, the term legacy access network refers to a network employing a third generation (3G) wireless communication technology based on a set of standards that complies with the International Mobile Telecommunications-2000 (IMT-2000) specifications or a fourth generation (4G) wireless communication technology based on a set of standards that comply with the International Mobile Telecommunications Advanced (ITU-Advanced) specification. For example, some the standards promulgated by the 3rd Generation Partnership Project (3GPP) and the 3rd Generation Partnership Project 2 (3GPP2) may comply with IMT-2000 and/or ITU-Advanced. Examples of such legacy standards defined by the 3rd Generation Partnership Project (3GPP) include, but are not limited to, Long-Term Evolution (LTE), LTE-Advanced, Evolved Packet System (EPS), and Universal Mobile Telecommunication System (UMTS). Additional examples of various radio access technologies based on one or more of the above-listed 3GPP standards include, but are not limited to, Universal Terrestrial Radio Access (UTRA), Evolved Universal Terrestrial Radio Access (eUTRA), General Packet Radio Service (GPRS) and Enhanced Data Rates for GSM Evolution (EDGE). Examples of such legacy standards defined by the 3rd Generation Partnership Project 2 (3GPP2) include, but are not limited to, CDMA2000 and Ultra Mobile Broadband (UMB). Other examples of standards employing 3G/4G wireless communication technology include the IEEE 802.16 (WiMAX) standard and other suitable standards.

As further used herein, the term next generation access network generally refers to a network employing continued evolved wireless communication technologies. This may include, for example, a fifth generation (5G) wireless communication technology based on a set of standards. The standards may comply with the guidelines set forth in the 5G White Paper published by the Next Generation Mobile Networks (NGMN) Alliance on Feb. 17, 2015. For example, standards that may be defined by the 3GPP following LTE-Advanced or by the 3GPP2 following CDMA2000 may comply with the NGMN Alliance 5G White Paper. Standards may also include pre-3GPP efforts specified by Verizon Technical Forum (www.vstgf) and Korea Telecom SIG (www.kt5g.org).

The geographic region covered by the access network 100 may be divided into a number of cellular regions (cells) that can be uniquely identified by a user equipment (UE) based on an identification broadcasted over a geographical from one access point or base station. FIG. 1 illustrates macrocells 102, 104, and 106, and a small cell 108, each of which may include one or more sectors. A sector is a sub-area of a cell. All sectors within one cell are served by the same base station. A radio link within a sector can be identified by a single logical identification belonging to that sector. In a cell that is divided into sectors, the multiple sectors within a cell can be formed by groups of antennas with each antenna responsible for communication with UEs in a portion of the cell.

In general, a base station (BS) serves each cell. Broadly, a base station is a network element in a radio access network responsible for radio transmission and reception in one or more cells to or from a UE. A BS may also be referred to by those skilled in the art as a base transceiver station (BTS), a radio base station, a radio transceiver, a transceiver function, a basic service set (BSS), an extended service set (ESS), an access point (AP), a Node B (NB), an eNode B (eNB), or some other suitable terminology.

In FIG. 1, two high-power base stations 110 and 112 are shown in cells 102 and 104; and a third high-power base station 114 is shown controlling a remote radio head (RRH) 116 in cell 106. That is, a base station can have an integrated antenna or can be connected to an antenna or RRH by feeder cables. In the illustrated example, the cells 102, 104, and 106 may be referred to as macrocells, as the high-power base stations 110, 112, and 114 support cells having a large size. Further, a low-power base station 118 is shown in the small cell 108 (e.g., a microcell, picocell, femtocell, home base station, home Node B, home eNode B, etc.) which may overlap with one or more macrocells. In this example, the cell 108 may be referred to as a small cell, as the low-power base station 118 supports a cell having a relatively small size. Cell sizing can be done according to system design as well as component constraints. It is to be understood that the access network 100 may include any number of wireless base stations and cells. Further, a relay node may be deployed to extend the size or coverage area of a given cell. The base stations 110, 112, 114, 118 provide wireless access points to a core network for any number of mobile apparatuses.

FIG. 1 further includes a quadcopter or drone 120, which may be configured to function as a base station. That is, in some examples, a cell may not necessarily be stationary, and the geographic area of the cell may move according to the location of a mobile base station such as the quadcopter 120.

In general, base stations may include a backhaul interface for communication with a backhaul portion of the network. The backhaul may provide a link between a base station and a core network, and in some examples, the backhaul may provide interconnection between the respective base stations. The core network is a part of a wireless communication system that is generally independent of the radio access technology used in the radio access network. Various types of backhaul interfaces may be employed, such as a direct physical connection, a virtual network, or the like using any suitable transport network. Some base stations may be configured as integrated access and backhaul (IAB) nodes, where the wireless spectrum may be used both for access links (i.e., wireless links with UEs), and for backhaul links. This scheme is sometimes referred to as wireless self-backhauling. By using wireless self-backhauling, rather than requiring each new base station deployment to be outfitted with its own hard-wired backhaul connection, the wireless spectrum utilized for communication between the base station and UE may be leveraged for backhaul communication, enabling fast and easy deployment of highly dense small cell networks.

The access network 100 is illustrated supporting wireless communication for multiple mobile apparatuses. A mobile apparatus is commonly referred to as user equipment (UE) in standards and specifications promulgated by the 3rd Generation Partnership Project (3GPP), but may also be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. A UE may be an apparatus that provides a user with access to network services.

Within the present document, a “mobile” apparatus need not necessarily have a capability to move, and may be stationary. The term mobile apparatus or mobile device broadly refers to a diverse array of devices and technologies. For example, some non-limiting examples of a mobile apparatus include a mobile, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an “Internet of things” (IoT). A mobile apparatus may additionally be an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A mobile apparatus may additionally be a digital home or smart home device such as a home audio, video, and/or multimedia device, an appliance, a vending machine, intelligent lighting, a home security system, a smart meter, etc. A mobile apparatus may additionally be a smart energy device, a security device, a solar panel or solar array, a municipal infrastructure device controlling electric power (e.g., a smart grid), lighting, water, etc.; an industrial automation and enterprise device; a logistics controller; agricultural equipment; military defense equipment, vehicles, aircraft, ships, and weaponry, etc. Still further, a mobile apparatus may provide for connected medicine or telemedicine support, i.e., health care at a distance. Telehealth devices may include telehealth monitoring devices and telehealth administration devices, whose communication may be given preferential treatment or prioritized access over other types of information, e.g., in terms of prioritized access for transport of critical service user data traffic, and/or relevant QoS for transport of critical service user data traffic.

Within the access network 100, the cells may include UEs that may be in communication with one or more sectors of each cell. For example, UEs 122 and 124 may be in communication with base station 110; UEs 126 and 128 may be in communication with base station 112; UEs 130 and 132 may be in communication with base station 114 by way of RRH 116; UE 134 may be in communication with low-power base station 118; and UE 136 may be in communication with mobile base station 120. Here, each base station 110, 112, 114, 118, and 120 may be configured to provide an access point to a core network (not shown) for all the UEs in the respective cells.

In another example, a mobile network node (e.g., quadcopter 120) may be configured to function as a UE. For example, the quadcopter 120 may operate within cell 102 by communicating with base station 110. In some aspects of the disclosure, two or more UE (e.g., UEs 126 and 128) may communicate with each other using peer to peer (P2P) or sidelink signals 127 without relaying that communication through a base station (e.g., base station 112).

Unicast or broadcast transmissions of control information and/or user data traffic from a base station (e.g., base station 110) to one or more UEs (e.g., UEs 122 and 124) may be referred to as downlink (DL) transmission, while transmissions of control information and/or user data traffic originating at a UE (e.g., UE 122) may be referred to as uplink (UL) transmissions. In addition, the uplink and/or downlink control information and/or user data traffic may be transmitted in transmission time intervals (TTIs). As used herein, the term TTI may refer to the inter-arrival time of a given schedulable set of control and/or user data traffic. In various examples, a TTI may be configured to carry one or more transport blocks, which are generally the basic data unit exchanged between the physical layer (PHY) and medium access control (MAC) layer (sometimes referred to as a MAC PDU, or protocol data unit). In accordance with various aspects of the present disclosure, a subframe may include one or more TTIs. Thus, as further used herein, the term subframe may refer to an encapsulated set of information including one or more TTIs, which is capable of being independently decoded. Multiple subframes may be grouped together to form a single frame or radio frame. Any suitable number of subframes may occupy a frame. In addition, a subframe may have any suitable duration (e.g., 250 μs, 500 μs, 1 ms, etc.).

The air interface in the access network 100 may utilize one or more multiplexing and multiple access algorithms to enable simultaneous communication of the various devices. For example, multiple access for uplink (UL) or reverse link transmissions from UEs 122 and 124 to base station 110 may be provided utilizing time division multiple access (TDMA), code division multiple access (CDMA), frequency division multiple access (FDMA), orthogonal frequency division multiple access (OFDMA), sparse code multiple access (SCMA), resource spread multiple access (RSMA), or other suitable multiple access schemes. Further, multiplexing downlink (DL) or forward link transmissions from the base station 110 to UEs 122 and 124 may be provided utilizing time division multiplexing (TDM), code division multiplexing (CDM), frequency division multiplexing (FDM), orthogonal frequency division multiplexing (OFDM), sparse code multiplexing (SCM), or other suitable multiplexing schemes.

Further, the air interface in the access network 100 may utilize one or more duplexing algorithms Duplex refers to a point-to-point communication link where both endpoints can communicate with one another in both directions. Full duplex means both endpoints can simultaneously communicate with one another. Half duplex means only one endpoint can send information to the other at a time. In a wireless link, a full duplex channel generally relies on physical isolation of a transmitter and receiver, and suitable interference cancellation technologies. Full duplex emulation is frequently implemented for wireless links by utilizing frequency division duplex (FDD) or time division duplex (TDD). In FDD, transmissions in different directions operate at different carrier frequencies. In TDD, transmissions in different directions on a given channel are separated from one another using time division multiplexing. That is, at some times the channel is dedicated for transmissions in one direction, while at other times the channel is dedicated for transmissions in the other direction, where the direction may change very rapidly, e.g., several times per subframe.

In the radio access network 100, the ability for a UE to communicate while moving, independent of their location, is referred to as mobility. The various physical channels between the UE and the radio access network are generally set up, maintained, and released under the control of a mobility management entity (MME). In various aspects of the disclosure, an access network 100 may utilize DL-based mobility or UL-based mobility to enable mobility and handovers (i.e., the transfer of a UE's connection from one radio channel to another). In a network configured for DL-based mobility, during a call with a scheduling entity, or at any other time, a UE may monitor various parameters of the signal from its serving cell as well as various parameters of neighboring cells. Depending on the quality of these parameters, the UE may maintain communication with one or more of the neighboring cells. During this time, if the UE moves from one cell to another, or if signal quality from a neighboring cell exceeds that from the serving cell for a given amount of time, the UE may undertake a handoff or handover from the serving cell to the neighboring (target) cell. For example, UE 124 may move from the geographic area corresponding to its serving cell 102 to the geographic area corresponding to a neighbor cell 106. When the signal strength or quality from the neighbor cell 106 exceeds that of its serving cell 102 for a given amount of time, the UE 124 may transmit a reporting message to its serving base station 110 indicating this condition. In response, the UE 124 may receive a handover command, and the UE may undergo a handover to the cell 106.

In a network configured for UL-based mobility, UL reference signals from each UE may be utilized by the network to select a serving cell for each UE. In some examples, the base stations 110, 112, and 114/116 may broadcast unified synchronization signals (e.g., unified Primary Synchronization Signals (PSSs), unified Secondary Synchronization Signals (SSSs) and unified Physical Broadcast Channels (PBCH)). The UEs 122, 124, 126, 128, 130, and 132 may receive the unified synchronization signals, derive the carrier frequency and subframe timing from the synchronization signals, and in response to deriving timing, transmit an uplink pilot or reference signal. The uplink pilot signal transmitted by a UE (e.g., UE 124) may be concurrently received by two or more cells (e.g., base stations 110 and 114/116) within the access network 100. Each of the cells may measure a strength of the pilot signal, and the access network (e.g., one or more of the base stations 110 and 114/116 and/or a central node within the core network) may determine a serving cell for the UE 124. As the UE 124 moves through the access network 100, the network may continue to monitor the uplink pilot signal transmitted by the UE 124. When the signal strength or quality of the pilot signal measured by a neighboring cell exceeds that of the signal strength or quality measured by the serving cell, the network 100 may handover the UE 124 from the serving cell to the neighboring cell, with or without informing the UE 124.

Although the synchronization signal transmitted by the base stations 110, 112, and 114/116 may be unified, the synchronization signal may not identify a particular cell, but rather may identify a zone of multiple cells operating on the same frequency and/or with the same timing. The use of zones in 5G networks or other next generation communication networks enables the uplink-based mobility framework and improves the efficiency of both the UE and the network, since the number of mobility messages that need to be exchanged between the UE and the network may be reduced.

In various implementations, the air interface in the access network 100 may utilize licensed spectrum, unlicensed spectrum, or shared spectrum. Licensed spectrum provides for exclusive use of a portion of the spectrum, generally by virtue of a mobile network operator purchasing a license from a government regulatory body. Unlicensed spectrum provides for shared use of a portion of the spectrum without need for a government-granted license. While compliance with some technical rules is generally still required to access unlicensed spectrum, generally, any operator or device may gain access. Shared spectrum may fall between licensed and unlicensed spectrum, wherein technical rules or limitations may be required to access the spectrum, but the spectrum may still be shared by multiple operators and/or multiple RATs. For example, the holder of a license for a portion of licensed spectrum may provide licensed shared access (LSA) to share that spectrum with other parties, e.g., with suitable licensee-determined conditions to gain access.

In some examples, access to the air interface may be scheduled, wherein a scheduling entity (e.g., a base station) allocates resources for communication among some or all devices and equipment within its service area or cell. Within the present disclosure, as discussed further below, the scheduling entity may be responsible for scheduling, assigning, reconfiguring, and releasing resources for one or more scheduled entities. That is, for scheduled communication, UEs or scheduled entities utilize resources allocated by the scheduling entity.

Base stations are not the only entities that may function as a scheduling entity. That is, in some examples, a UE may function as a scheduling entity, scheduling resources for one or more scheduled entities (e.g., one or more other UEs). In other examples, sidelink signals may be used between UEs without necessarily relying on scheduling or control information from a base station. For example, UE 138 is illustrated communicating with UEs 140 and 142. In some examples, the UE 138 is functioning as a scheduling entity or a primary sidelink device, and UEs 140 and 142 may function as a scheduled entity or a non-primary (e.g., secondary) sidelink device. In still another example, a UE may function as a scheduling entity in a device-to-device (D2D), peer-to-peer (P2P), or vehicle-to-vehicle (V2V) network, and/or in a mesh network. In a mesh network example, UEs 140 and 142 may optionally communicate directly with one another in addition to communicating with the scheduling entity 138.

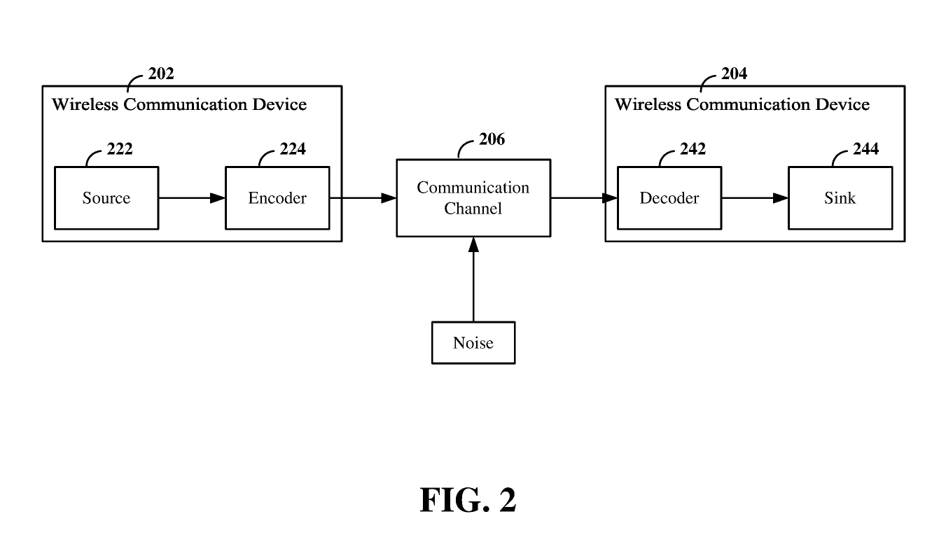

FIG. 2 is a schematic illustration of wireless communication between a first wireless communication device 202 and a second wireless communication device 204. Each wireless communication device 202 and 204 may be a user equipment (UE), a base station, or any other suitable apparatus or means for wireless communication. In the illustrated example, a source 222 within the first wireless communication device 202 transmits a digital message over a communication channel 206 (e.g., a wireless channel) to a sink 244 in the second wireless communication device 204. One issue in such a scheme that must be addressed to provide for reliable communication of the digital message, is to take into account the noise that affects the communication channel 206.

Block codes, or error correcting codes are frequently used to provide reliable transmission of digital messages over such noisy channels. In a typical block code, an information message or sequence is split up into blocks, each block having a length of K bits. An encoder 224 at the first (transmitting) wireless communication device 202 then mathematically adds redundancy to the information message, resulting in codewords having a length of N, where N>K. Here, the code rate R is the ratio between the message length and the block length: i.e., R=K/N. Exploitation of this redundancy in the encoded information message is the key to reliability of the message, enabling correction for any bit errors that may occur due to the noise. That is, a decoder 242 at the second (receiving) wireless communication device 204 can take advantage of the redundancy to reliably recover the information message even though bit errors may occur, in part, due to the addition of noise to the channel.

Many examples of such error correcting block codes are known to those of ordinary skill in the art, including Hamming codes, Bose-Chaudhuri-Hocquenghem (BCH) codes, turbo codes, and low-density parity check (LDPC) codes, among others. Many existing wireless communication networks utilize such block codes, such as 3GPP LTE networks, which utilize turbo codes; and IEEE 802.11n Wi-Fi networks, which utilize LDPC codes. However, for future networks, a new category of block codes, called polar codes, presents a potential opportunity for reliable and efficient information transfer with improved performance relative to turbo codes and LDPC codes.

Polar codes are linear block error correcting codes invented in 2007 by Erdal Arikan, and currently known to those skilled in the art. In general terms, channel polarization is generated with a recursive algorithm that defines polar codes. Polar codes are the first explicit codes that achieve the channel capacity of symmetric binary-input discrete memoryless channels. That is, polar codes achieve the channel capacity (the Shannon limit) or the theoretical upper bound on the amount of error-free information that can be transmitted on a discrete memoryless channel of a given bandwidth in the presence of noise.

Polar codes may be considered as block codes (N, K). The codeword length N is a power of 2 (e.g., 256, 512, 1024, etc.) because the original construction of a polarizing matrix is based on the Kronecker product of

$$[ \begin{matrix}1 & 0 \\ 1 & 1\end{matrix} ] .$$

For example, a generator matrix (e.g., a polarizing matrix) G_{N} for generating a polar code with a block length of N can be expressed as:

G_{N}=B_{N}

[symbol]

Here, B_{N} is the bit-reversal permutation matrix for successive cancellation (SC) decoding (functioning in some ways similar to the interleaver function used by a turbo coder in LTE networks), and [symbol] is the n^{th} Kronecker power of F. The basic matrix F is

$$[ \begin{matrix}1 & 0 \\ 1 & 1\end{matrix} ] .$$

The matrix [symbol] is generated by raising the basic 2×2 matrix F by the n^{th} Kronecker power. This matrix is a lower triangular matrix, in that all the entries above the main diagonal are zero. Because the bit-reversal permutation just changes the index of the rows, the matrix of [symbol] may be analyzed instead. The matrix of [symbol] can be expressed as:

$${F}^{⊗ n} = [ \begin{matrix}\begin{matrix}1 & 0 & 0 \\ 1 & 1 & 0 \\ 1 & 0 & 1\end{matrix} & … & \begin{matrix}0 & 0 & 0 & 0 \\ 0 & 0 & 0 & 0 \\ 0 & 0 & 0 & 0\end{matrix} \\ ⋮ & ⋱ & ⋮ \\ \begin{matrix}1 & 0 & 0 \\ 1 & 1 & 0 \\ 1 & 0 & 1 \\ 1 & 1 & 1\end{matrix} & … & \begin{matrix}1 & 0 & 0 & 0 \\ 1 & 1 & 0 & 0 \\ 1 & 0 & 1 & 0 \\ 1 & 1 & 1 & 1\end{matrix}\end{matrix} ]$$

The encoder 224 may then generate a polar code as:

x₁^{N}=u₁^{N}G_{N}=u₁^{N}B_{N}

[symbol]

where x₁^{N}=(x₁, x₂, . . . , x_{N}) is the encoded bit sequence, and u₁^{N}=(u₁, u₂, . . . , u_{N}) is the encoding bit sequence.

The receiving wireless communication device 204 receives a noisy version of x, and has to decode x or, equivalently, u. Polar codes may be decoded with a simple successive cancellation (SC) decoder, which has a decoding complexity of O (N log N) and can achieve Shannon capacity when N is very large. However, for short and moderate block lengths, the error rate performance of polar codes significantly degrades. Therefore, SC-list decoding may be utilized to improve the polar coding error rate performance. With SC-list decoding, instead of only keeping one decoding path (as in simple SC decoders), L decoding paths are maintained, where L>1. At each decoding stage, the decoder 242 discards the least probable (worst) decoding paths and keeps only the L best decoding paths. For example, instead of selecting a value uᵢ at each decoding stage, two decoding paths corresponding to either possible value of uᵢ are created and decoding is continued in two parallel decoding threads (2*L). To avoid the exponential growth of the number of decoding paths, at each decoding stage, only the L most likely paths are retained. At the end, the decoder 242 will have a list of L candidates for u₁^{N}, out of which the most likely candidate is selected. Thus, when the decoder 242 completes the SC-list decoding algorithm, the decoder 242 returns a single codeword to the sink 244.

A conventional polar code list decoder requires (L−1) cycles/time slots to perform a path metric update by selecting the L most likely decoding paths for a single decoding stage. For example, during the first cycle for a decoding stage, the decoding path with the lowest path metric may be selected for the next decoding stage. During each cycle for that decoding stage, the polar code list decoder may further compare path metrics of candidate decoding paths and select the best decoding path from the candidate decoding paths as one of the other L decoding paths. In some examples, the candidate decoding paths may include previously unselected decoding paths and may include a subset of the previously unselected 2*L decoding paths. For example, if L=4, the polar code list decoder typically requires 3 cycles to select the 4 most likely decoding paths for the next decoding stage.

In various aspects of the disclosure, to reduce the number of cycles to complete the path metric update, the polar code list decoder 242 may pipeline the decoding stages to complete a path metric update each cycle. For example, during each cycle, the polar code list decoder 242 may simultaneously compare path metrics of candidate decoding paths for (L−1) decoding stages and select the best decoding paths from the respective candidate decoding paths for each of the (L−1) decoding stages. Since the candidate decoding paths for each decoding stage are determined based on the L decoding paths selected in previous decoding stages, during each cycle, the candidate decoding paths for a particular selected decoding path may include only a subset of the potential 2*L candidate decoding paths based on the number of decoding paths that have already been selected in the previous decoding stage.

In general, the L decoding paths for a particular decoding stage may be selected in order, where the first selected decoding path has the lowest (best) path metric, the second selected decoding path has the second lowest (second best) path metric, the third selected decoding path has the third lowest (third best) path metric and so on until the Lth decoding path with the Lth best path metric is selected. Thus, for the next decoding stage, the candidate decoding paths for one of the L selected decoding paths may be easily determined from knowledge of the path metrics of the L decoding paths from the previous decoding stage (e.g., the path metrics are in order from lowest to highest).

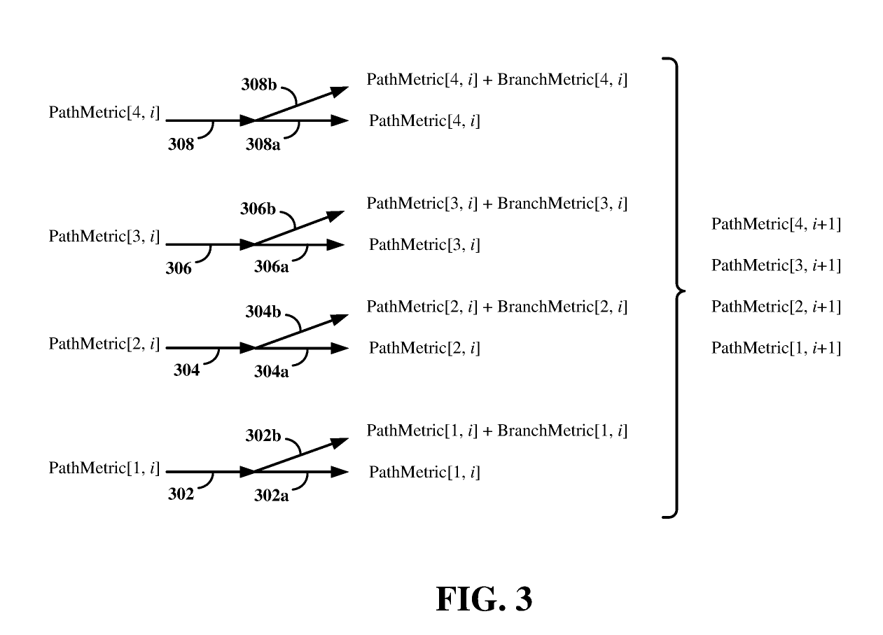

For example, with reference to FIG. 3, an example of polar code list decoding with a list size L of 4 is illustrated. In decoding stage i, four decoding paths 302-308 selected by the previous decoding stage are shown. Each decoding path 302-308 has a respective path metric. For example, decoding path 302 has a path metric of PathMetric[1,i], decoding path 304 has a path metric of PathMetric[2,i], decoding path 306 has a path metric of PathMetric[3,i] and decoding path 308 has a path metric of PathMetric[4,i]. The path metrics are shown listed in order, where decoding path 302 has the lowest (best) path metric PathMetric[1,i], and PathMetric[1,i]<PathMetric[2,i]<PathMetric [symbol] [3,i]<PathMetric[4,i].

In decoding stage i, each of the decoding paths 302-308 selected by the previous decoding stage are split into two decoding paths (e.g., a root/initial decoding path and a branch decoding path) to create 2*L or 8 candidate decoding paths. For example, decoding path 302 is split into decoding paths 302a and 302b, decoding path 304 is split into decoding paths 304a and 304b, decoding path 306 is split into decoding paths 306a and 306b, and decoding path 308 is split into decoding paths 308a and 308b. Each of these candidate decoding paths also has a respective path metric associated with it. For example, root/initial decoding paths 302a, 304a, 306a and 308a retain the path metrics from the previous stage, while branch decoding paths 302b, 304b, 306b and 308b each add a branch metric to the path metric from the previous stage. As an example, decoding path 302b has a path metric of PathMetric[1,i]+BranchMetric[1,i] From the 8 candidate decoding paths, the 4 most likely decoding paths (e.g., the 4 decoding paths with the lowest path metrics) are selected for the next decoding stage i+1. The path metrics for each of the selected decoding paths for the next decoding stage may then be represented as PathMetric[1, i+1], PathMetric[2, i+1], PathMetric[3, i+1], and PathMetric[4, i+1], wherein PathMetric[1, i+1] is the lowest (best) path metric.

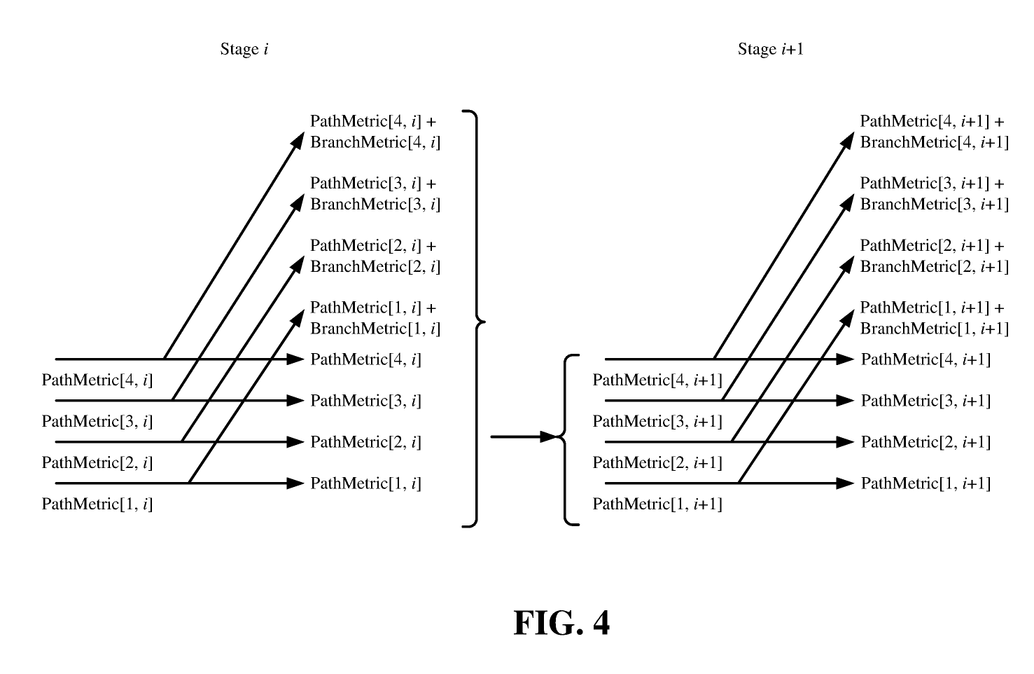

Referring now to FIG. 4, in decoding stage i+1, the 4 selected decoding paths from decoding stage i may then each be split into two decoding paths to again produce 8 candidate decoding paths. Each of the 8 candidate decoding paths also has a respective path metric, as shown in FIG. 4. The process may then be repeated to select the 4 best decoding paths (e.g., the 4 paths with the lowest path metrics) for the next stage.

The action in each stage corresponds to the decoding of a bit in the u-domain (e.g., the set containing both frozen bits and information bits) for all the lists, and each list represents a set of information bits that have already been decoded. During the successive-cancellation decoding process (polar successive cancellation decoder), for the i^{th} stage, each list may obtain a log-likelihood ratio (LLR) regarding the i^{th} bit in the u-domain. The path metric corresponding to list 1 after the (i−1)^{th} stage may be denoted as PathMetric[1,i−1], and the LLR obtained for list 1 during the i^{th} stage may be denoted as LLR[1,i]. Thus, after the LLR is obtained, each list is expanded into two candidates, with the following two metrics: (1) PathMetric[l, i−1]; and (2) PathMetric[l, i−1]+|LLR[l, i].

The list candidate that corresponds to the first metric represents the case when the i^{th} decoded bit is the same as the hard-decision from LLR[1,i], whereas the list candidate that corresponds to the second metric represents the case when the i^{th} decoded bit is different from the hard-decision from LLR[1,i] (e.g., the hard decision of an LLR is ½−½×LLR). If the i^{th} bit is a frozen bit, then only one of the two candidates will be valid.

If the list size is L, and the i^{th} bit is not a frozen bit, then after each stage, there will be 2*L list candidates, with the following metrics:

$$PathMetric [ 1 , i - 1 ]$$

$$PathMetric [ 1 , i - 1 ] + \vert LLR [ 1 , i ] \vert$$

$$PathMetric [ 2 , i - 1 ]$$

$$PathMetric [ 2 , i - 1 ] + \vert LLR [ 2 , i ] \vert$$

$$…$$

$$PathMetric [ L , i - 1 ]$$

$$PathMetric [ L , i - 1 ] + \vert LLR [ L , i ] \vert$$

The 2L candidate lists may then be sorted based on their metrics, and only L out of the 2L candidates with the smallest metrics may be kept. In other words, only half of the list candidates with the smallest metrics may be kept. Further, the L selected lists may be arranged in such a way that the l^{th} list has the l^{th} smallest path metric. In accordance with aspects of the disclosure, the operation of sorting and selecting the L best list candidates in each stage may be pipelined.

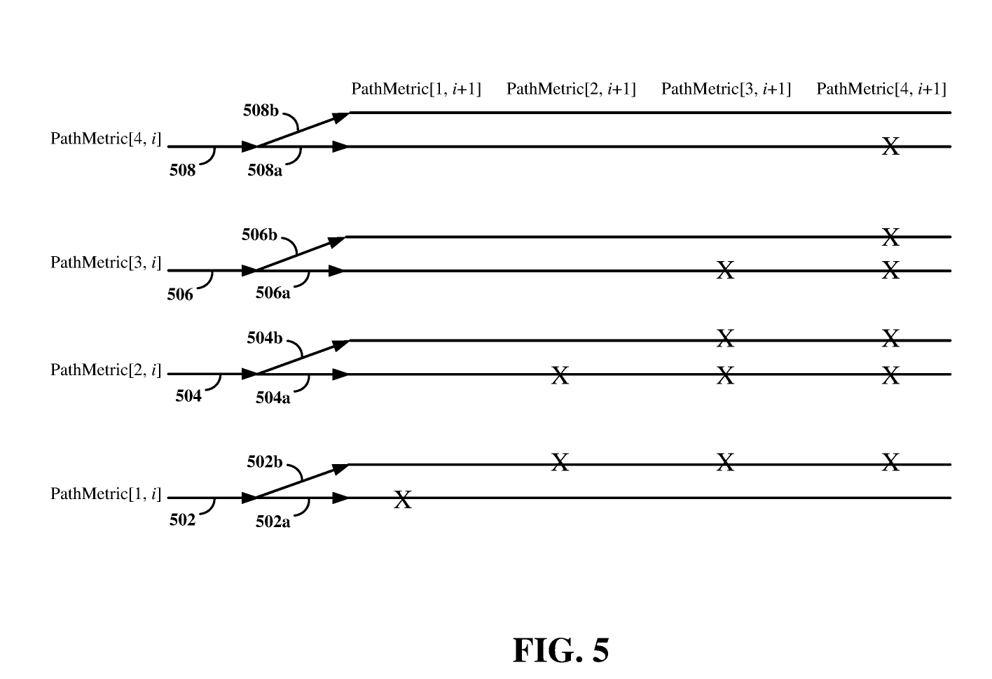

FIG. 5 illustrates an example of decoding path selection in polar code list decoding. Using the example from FIG. 3, with a list size L of 4, the 4 most likely decoding paths may be selected from the 8 candidate decoding paths 302a, 302b, 304a, 304b, 306a, 306b, 308a, and 308b with knowledge of the path metric rankings of the decoding paths 302, 304, 306, and 308 selected by the previous decoding stage. As indicated in FIG. 5, the path metric PathMetric[1,i] of decoding path 302 is the lowest (best) path metric, and PathMetric[1,i]<PathMetric[2,i]<PathMetric[3,i]<PathMetric[4,i]. Thus, since candidate decoding path 302a retains the path metric PathMetric[1,i] of decoding path 302, candidate decoding path 302a must necessarily have the lowest path metric of the candidate decoding paths. As such, candidate decoding path 302a may be selected as the first decoding path for the next decoding stage and will maintain the lowest path metric PathMetric[1,i+1] in the next decoding stage.

Of the remaining (unselected) candidate decoding paths, the candidate decoding path with the second lowest path metric may be either candidate decoding path 302b or candidate decoding path 304a. This may be deduced from the path metric rankings discussed above (e.g., candidate decoding path 304a retains the second lowest previous path metric from decoding path 304) and the fact that the path metric for candidate decoding path 302b is based on the path metric of decoding path 302 with the addition of a branch metric (e.g., PathMetric[1,i]+BranchMetric[1, i]). Therefore, the second selected decoding path will be one of candidate decoding path 302b or 304a, whichever has the second lowest path metric PathMetric[2,i+1] for the next decoding stage.

Similarly, the third decoding path with the third lowest path metric selected for the next decoding stage will be selected from the remaining (unselected) candidate decoding paths of candidate decoding paths 302b, 304a, 304b and 306a. This may be deduced from the path metric rankings discussed above and the branch metrics. Therefore, the third selected decoding path will be one of candidate decoding path 302b, 304a, 304b and 306a, whichever was not selected as the second decoding path and has the third lowest path metric PathMetric[3,i+1] for the next decoding stage. Likewise, the fourth decoding path with the fourth lowest path metric selected for the next decoding stage will be selected from the remaining (unselected) candidate decoding paths of candidate decoding paths 302b, 304a, 304b, 306a, 306b, and 308a.

Therefore, each decoding path may be selected from a respective subset of the candidate decoding paths. Various aspects of the disclosure leverage this fact to enable pipelining of the decoding stages, thus reducing the number of cycles between each path metric update to just one cycle.

For example, at the end of a first cycle (Cycle i), the path metric update for decoding stage i may be completed, at the end of a second cycle (Cycle i+1), the path metric update for decoding stage i+1 may be completed, at the end of a third cycle (Cycle i+2), the path metric update for decoding stage i+2 may be completed and so on. This may be accomplished by simultaneously selecting a decoding path in L−1 decoding stages during each of the cycles. For example, during Cycle i, the fourth decoding stage having the fourth lowest path metric may be selected in decoding stage i, the third decoding stage having the third lowest path metric may be selected in decoding stage i+1, and the first and second decoding stages having the first and second lowest path metrics may be selected in decoding stage i+2. As indicated before, the first decoding stage is known, as it is the candidate decoding stage with the same path metric as the lowest path metric from the previous decoding stage.

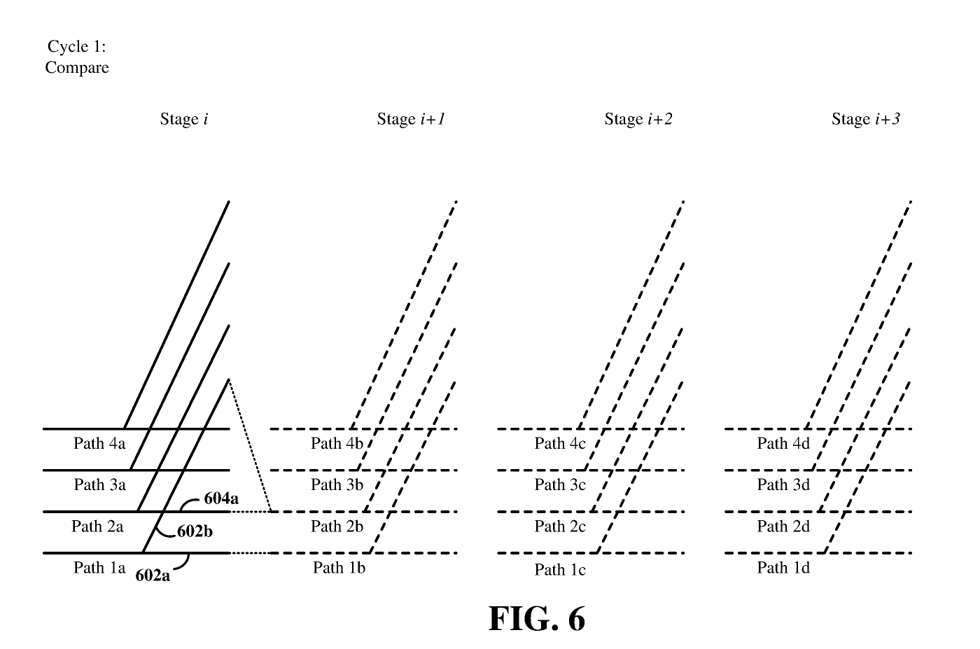

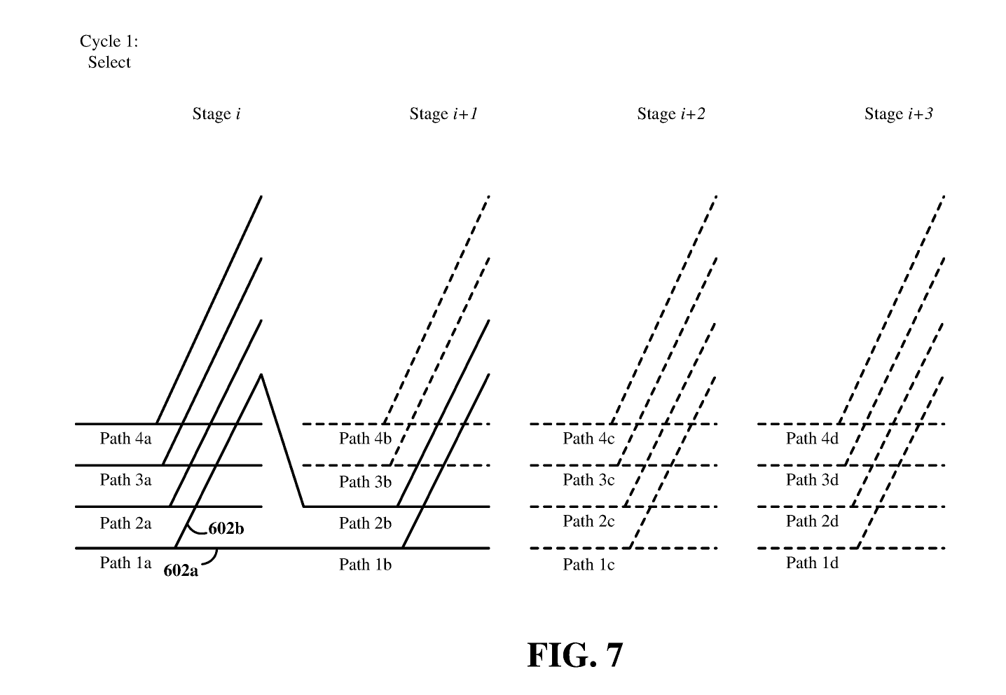

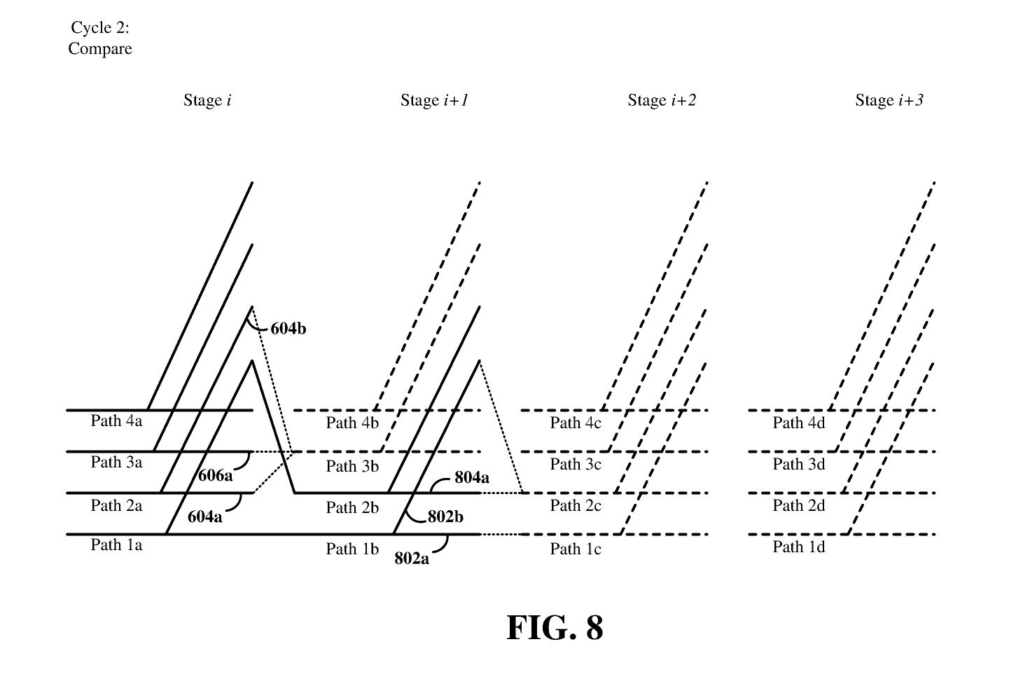

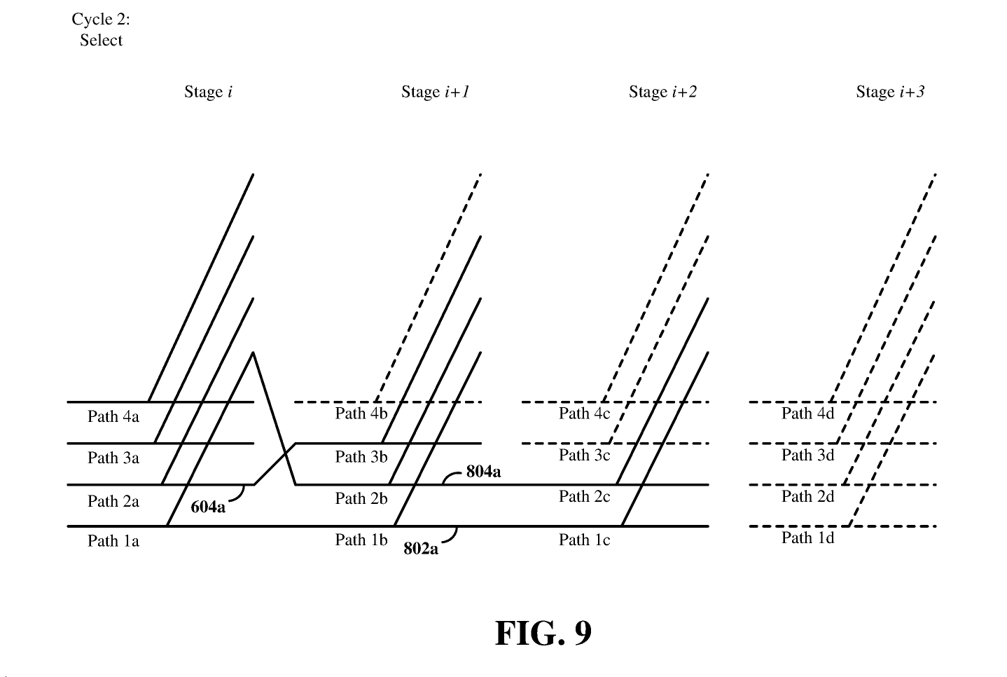

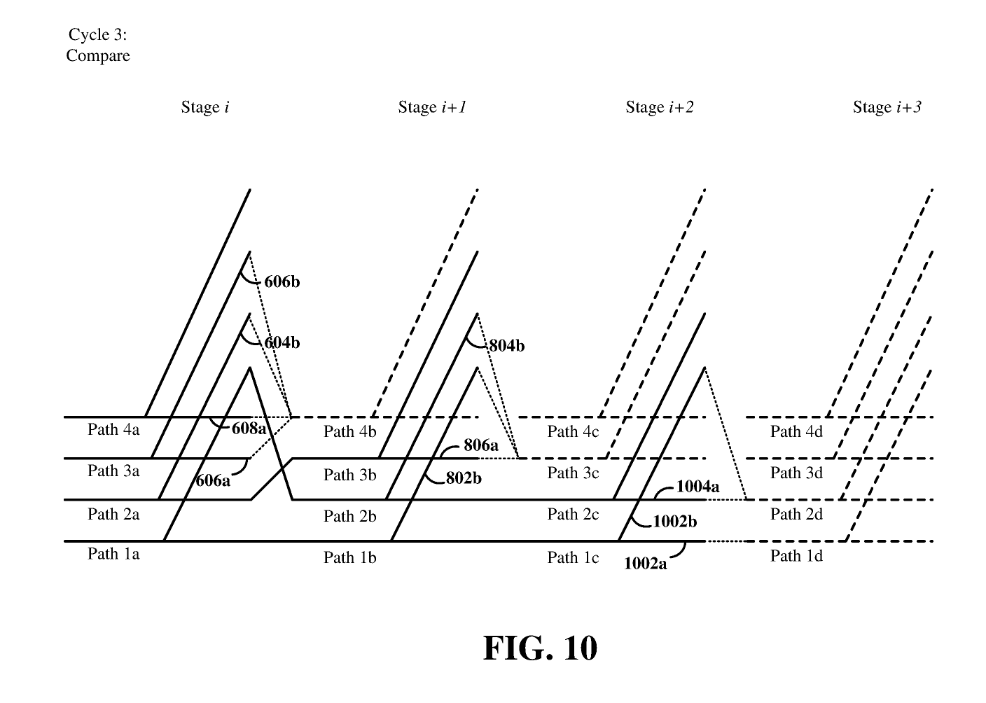

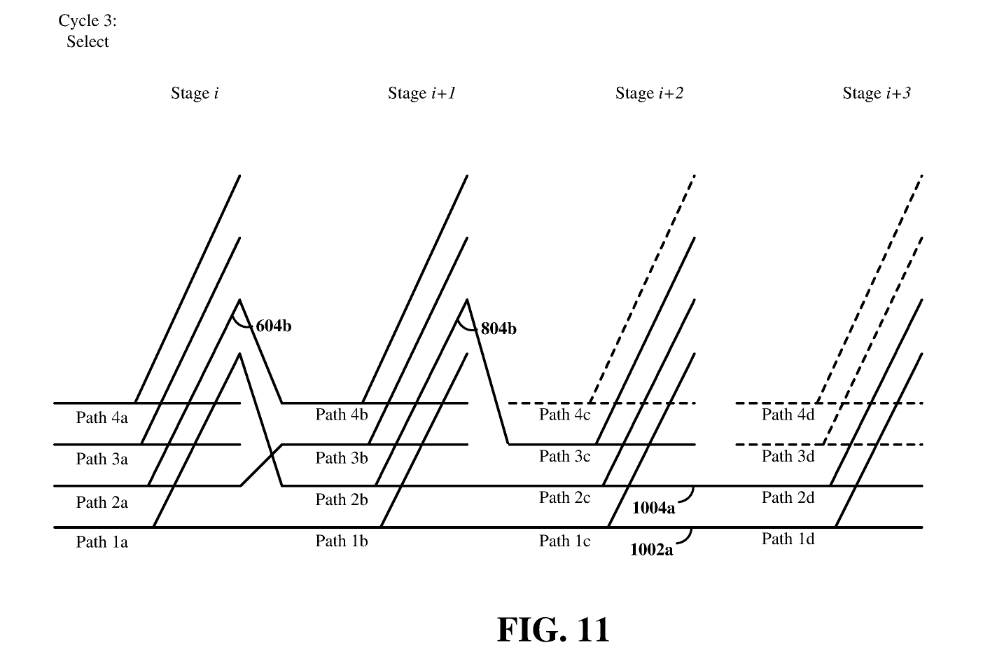

FIGS. 6-11 illustrate an example of pipelining decoding stages in polar code list decoding. FIGS. 6 and 7 illustrate exemplary decoding path selections performed in a first cycle/slot (Cycle 1), FIGS. 8 and 9 illustrate exemplary decoding path selections performed in a second cycle/slot (Cycle 2), and FIGS. 10 and 11 illustrate exemplary decoding path selections performed in a third cycle/slot (Cycle 3). In Cycle 1, as shown in FIG. 6, the first candidate decoding path 602a in decoding stage i is selected as the first decoding path (Path 1b) for the next decoding stage i+1 and the path metrics of the two candidate decoding paths 602b and 604a in decoding stage i for the second decoding path (Path 2b) in decoding stage i+1 are compared. In the example shown in FIG. 7, the candidate decoding path 602b corresponding to the branch of Path 1a in decoding stage i is selected as the second decoding path (Path 2b) for decoding stage i+1, and thus, at the end of Cycle 1, the first decoding path (Path 1b) and the second decoding path (Path 2b) for decoding stage i+1 have been selected.

In Cycle 2, as shown in FIG. 8, the path metrics of the three remaining (unselected) candidate decoding paths 604a, 604b, and 606a in decoding stage i for the third decoding path (Path 3b) in decoding stage i+1 are compared. From FIG. 5, it is known that the third decoding path may be selected from the subset of candidate decoding paths including the branch of Path 1a, Path 2a, the branch of Path 2a and Path 3a. Since the branch of Path 1a (decoding candidate 602b) was previously selected as the second decoding path (Path 2b) for the decoding stage i+1, the remaining candidate decoding paths (e.g., Path 2a corresponding to candidate decoding path 604a, the branch of Path 2a corresponding to candidate decoding path 604b, and Path 3a corresponding to candidate decoding path 606a) in this subset may be compared.

In addition, since the first and second decoding paths (Paths 1b and 2b) for decoding stage i+1 were previously selected in Cycle 1, the candidate decoding paths in stage i+1 for the first and second decoding paths (Paths 1c and 2c) in decoding stage i+2 may be determined. Therefore, in Cycle 2, the first candidate decoding path 802a in decoding stage i+1 may be selected as the first decoding path (Path 1c) for the next decoding stage i+2 and the path metrics of the two candidate decoding paths 802b and 804a for the second decoding path (Path 2c) in decoding stage i+2 may be compared. In the example shown in FIG. 9, at the end of Cycle 2, candidate decoding path 604a in decoding stage i was selected as the third decoding path (Path 3b) for decoding stage i+1, while candidate decoding path 804a in decoding stage i+1 was selected as the second decoding path (Path 2c) for decoding stage i+2.

In Cycle 3, as shown in FIG. 10, the path metrics of the four remaining (unselected) candidate paths 604b, 606a, 606b, and 608a in decoding stage i for the fourth decoding path (Path 4b) in decoding stage i+1 are compared. From FIG. 5, it is known that the fourth decoding path may be selected from the subset of candidate decoding paths including the branch of Path 1a, Path 2a, the branch of Path 2a, Path 3a, the branch of Path 3a and Path 4a. Since the branch of Path 1a corresponding to candidate decoding paths 602b and Path 2a corresponding to candidate decoding path 604a were previously selected as the second and third decoding paths (Paths 2b and 3b), respectively, in decoding stage i+1, the remaining candidate decoding paths (e.g., the branch of Path 2a corresponding to candidate decoding path 604b, Path 3a corresponding to candidate decoding path 606a, the branch of Path 3a corresponding to candidate decoding path 606b, and Path 4a corresponding to candidate decoding path 608a) in this subset may be compared.

In addition, since the first, second and third decoding paths (Paths 1b, 2b, and 3b) for decoding stage i+1 were previously selected in Cycles 1 and 2, the candidate decoding paths in stage i+1 for the third decoding path (Path 3c) in decoding stage i+2 may be determined. Therefore, in Cycle 3, the path metrics of the three remaining (unselected) candidate paths in decoding stage i+1 for the third decoding path (Path 3c) in decoding stage i+2 are compared. From FIG. 5, it is known that the third decoding path may be selected from the subset of candidate decoding paths including the branch of Path 1b, Path 2b, the branch of Path 2b and Path 3b in decoding stage i+1. Since path 2b corresponding to candidate decoding path 804a was previously selected as the second decoding path (Path 2c) for decoding stage i+2, the remaining candidate decoding paths (e.g., the branch of Path 1b corresponding to candidate decoding path 802b, the branch of Path 2b corresponding to candidate decoding path 804b and Path 3b corresponding to candidate decoding path 806a) in this subset may be compared.

Furthermore, since the first and second decoding paths (Paths 1c and 2c) for decoding stage i+2 were previously selected in Cycle 2, the candidate decoding paths in stage i+2 for the first and second decoding paths (Paths 1d and 2d) in decoding stage i+3 may be determined. Therefore, in Cycle 3, the first candidate decoding path 1002a in decoding stage i+2 may be selected as the first decoding path (Path 1d) for the next decoding stage i+3 and the path metrics of the two candidate decoding paths 1002b and 1004a for the second decoding path (Path 2d) in decoding stage i+3 may be compared. In the example shown in FIG. 11, at the end of Cycle 3, the branch of Path 2a corresponding to candidate decoding path 604b in decoding stage i was selected as the fourth decoding path (Path 4b) for decoding stage i+1, the branch of Path 2b corresponding to candidate decoding path 804b in decoding stage i+1 was selected as the third decoding path (Path 3c) for decoding stage i+2, and Path 2c corresponding to candidate decoding path 1004a in decoding stage i+2 was selected as the second decoding path (Path 2d) for decoding stage i+3.

As such, at the end of Cycle 3, the path metric update for decoding stage i has been completed. Although not shown, it can be easily ascertained that in the next cycle (e.g., Cycle 4), the path metric update for decoding stage i+1 will be completed (e.g., the fourth decoding path for decoding stage i+2 will be selected, along with the third decoding path for decoding stage i+3), and then in Cycle 5, the path metric update for decoding stage i+2 will be completed (e.g., the fourth decoding path for decoding stage i+3 will be selected). Therefore, beginning with Cycle 3 (after the four paths are initially created), a path metric update may be completed every cycle.

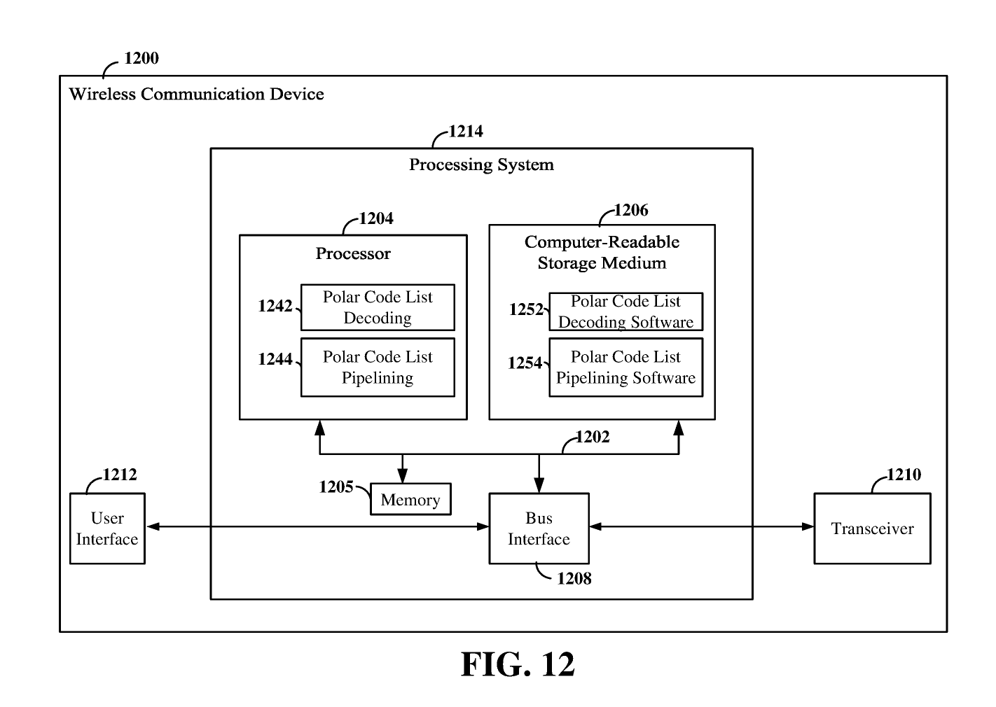

FIG. 12 is a conceptual diagram illustrating an example of a hardware implementation for an exemplary wireless communication device 1200 employing a processing system 1214. For example, the wireless communication device 1200 may be a user equipment (UE), a base station, or any other suitable apparatus or means for wireless communication.

The wireless communication device 1200 may be implemented with a processing system 1214 that includes one or more processors 1204. Examples of processors 1204 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the wireless communication device 1200 may be configured to perform any one or more of the functions described herein. That is, the processor 504, as utilized in a wireless communication device 1200, may be used to implement any one or more of the processes described and illustrated in FIGS. 3-11 and 13-15.

In this example, the processing system 1214 may be implemented with a bus architecture, represented generally by the bus 1202. The bus 1202 may include any number of interconnecting buses and bridges depending on the specific application of the processing system 1214 and the overall design constraints. The bus 1202 communicatively couples together various circuits including one or more processors (represented generally by the processor 1204), a memory 1205, and computer-readable media (represented generally by the computer-readable medium 1206). The bus 1202 may also link various other circuits such as timing sources, peripherals, voltage regulators, and power management circuits, which are well known in the art, and therefore, will not be described any further. A bus interface 1208 provides an interface between the bus 1202 and a transceiver 1210. The transceiver 1210 provides a means for communicating with various other apparatus over a transmission medium (e.g., air). Depending upon the nature of the apparatus, a user interface 1212 (e.g., keypad, display, speaker, microphone, joystick) may also be provided.

The processor 1204 is responsible for managing the bus 1202 and general processing, including the execution of software stored on the computer-readable medium 1206. The software, when executed by the processor 1204, causes the processing system 1214 to perform the various functions described below for any particular apparatus. The computer-readable medium 1206 and the memory 1205 may also be used for storing data that is manipulated by the processor 1204 when executing software.

One or more processors 1204 in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium 1206. The computer-readable medium 1206 may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium 1206 may reside in the processing system 1214, external to the processing system 1214, or distributed across multiple entities including the processing system 1214. The computer-readable medium 1206 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

In some aspects of the disclosure, the processor 1204 may include circuitry configured for various functions. For example, the processor 1204 may include polar code list decoding circuitry 1242 configured to receive a polar coded information transmission and perform successive-cancellation list decoding of the polar coded information transmission. In some examples, the polar coded information transmission includes a codeword of a plurality of successive data bits. For example, the polar code list decoding circuitry 1242 may create a list of L decoding paths to provide a list of L candidates for the bit sequence corresponding to the codeword. From the L candidates, the most likely candidate is selected as the codeword. Thus, with polar code list decoding, instead of only keeping one decoding path (as in simple successive-cancellation list decoders), L decoding paths are maintained, where L>1. At each decoding stage, the polar code list decoding circuitry 1242 receives L candidate bit values for a current bit being decoded from a previous decoding stage, creates two decoding paths corresponding to either possible value of each candidate bit value to produce 2*L candidate decoding paths, computes path metrics for each of the candidate decoding paths and discards the least probable (worst) decoding paths to keep only the L best decoding paths for the next decoding stage. The computed path metrics in each decoding stage may be stored, for example, in memory 1205 for use in selecting the L best decoding paths and the final bit sequence from the L codeword candidates. The polar code list decoding circuitry 1242 may operate in coordination with polar code list decoding software 1252.

The processor 1204 may further include polar code list pipelining circuitry 1244, configured for pipelining decoding stages during polar code list decoding. For example, the polar code list pipelining circuitry 1244 may be configured to select decoding paths in multiple decoding stages within each cycle. In some examples, the polar code list pipelining circuitry 1244 may be configured to operate in coordination with the polar code list decoding circuitry 1242 to complete a path metric update each cycle by pipelining multiple decoding stages. The polar code list pipelining circuitry 1244 may determine the number of pipelined decoding stages for a single cycle based on, for example, the list size L. In an example, the number of pipelined decoding stages may be equal to L−1.

In an example, with a list size L of 3, during a single cycle, the polar code list pipelining circuitry 1244 may be configured to compare respective first path metrics for each of a plurality of first decoding paths of a first decoding stage and select one of the first decoding paths for a second decoding stage following the first decoding stage, and compare respective second path metrics for each of a plurality of second decoding paths of the second decoding stage and select one of the second decoding paths for a third decoding stage following the second decoding stage. In another example, with a list size L of 4, during the same single cycle, the polar code list pipelining circuitry 1244 may further be configured to compare respective third path metrics for each of a plurality of third decoding paths of the third decoding stage and select one of the plurality of third decoding paths for a fourth decoding stage following the third decoding stage. For list sizes L greater than 4, during the same single cycle, the polar code list pipelining circuitry 1244 may further compare respective path metrics and select a respective decoding path for one or more additional decoding stages based on the number of pipelined decoding stages. The polar code list pipelining circuitry 1244 may operate in coordination with polar code list pipelining software 1254.

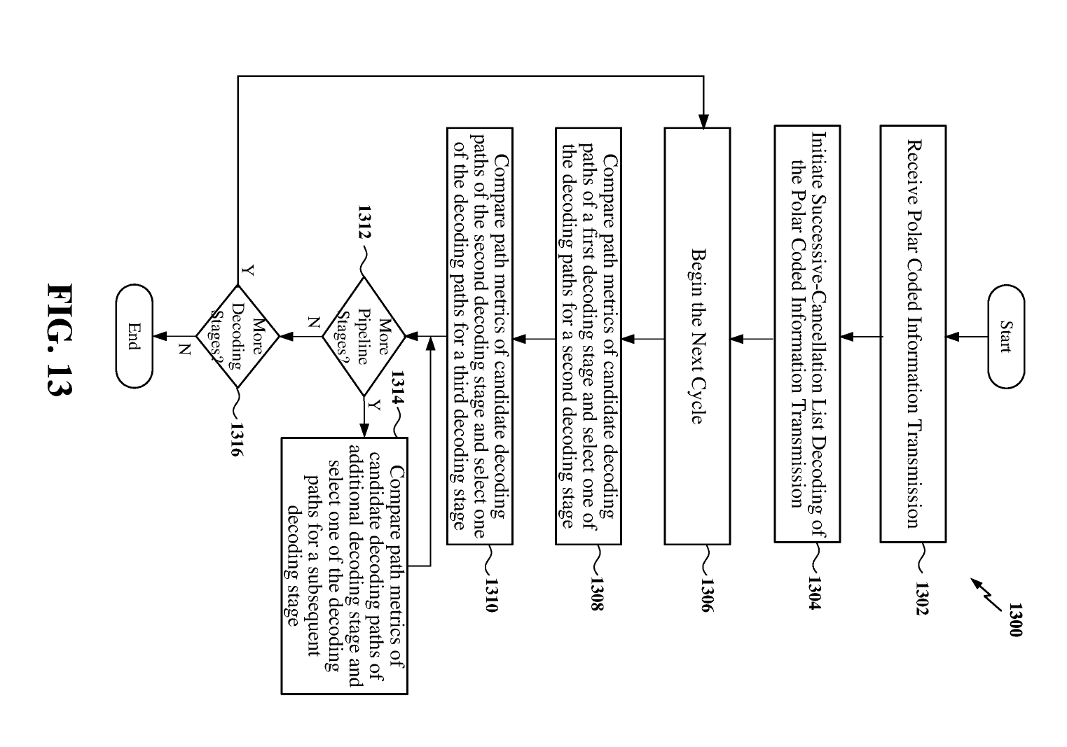

FIG. 13 is a flow chart illustrating an exemplary process 1300 for pipelining decoding stages in polar code list decoding in accordance with some aspects of the present disclosure. As described below, some or all illustrated features may be omitted in a particular implementation within the scope of the present disclosure, and some illustrated features may not be required for implementation of all embodiments. In some examples, the process 1300 may be carried out by the wireless communication device illustrated in FIG. 12. In some examples, the process 1300 may be carried out by any suitable apparatus or means for carrying out the functions or algorithm described below.

At block 1302, the wireless communication device may receive a polar coded information transmission. In some examples, the polar coded information transmission includes a codeword of a plurality of successive data bits. At block 1304, the wireless communication device may initiate successive-cancellation (SC) list decoding of the polar coded information transmission. For example, the polar code list decoding circuitry 1242 shown and described above in reference to FIG. 12 may receive the polar coded information transmission and initiate the SC list decoding.

At block 1306, the wireless communication device may begin the next cycle of decoding, and at block 1308, compare path metrics of candidate decoding paths of a first decoding stage and select one of the candidate decoding paths for a second decoding stage. During the same cycle, at block 1310, the wireless communication device may further compare path metrics of candidate decoding paths of the second decoding stage and select one of the candidate decoding paths for a third decoding stage. At block 1312, the wireless communication device may determine if there are additional pipeline stages (e.g., based on the list size L). If there are additional pipeline stages (Y branch of 1312), during the same cycle, at block 1314, the wireless communication device may compare path metrics of candidate decoding paths of an additional decoding stage (e.g., the third decoding stage) and select one of the candidate decoding paths for a subsequent decoding stage (e.g., the fourth decoding stage). At blocks 1312 and 1314, the wireless communication device may continue comparing path metrics of candidate decoding paths of additional decoding stages until the number of pipelined stages is reached (N branch of 1312). For example, the polar code list pipelining circuitry 1244 together with the polar code list decoding circuitry 1242 shown and described in reference to FIG. 12 may compare path metrics and select decoding paths for multiple pipelined decoding stages during the same single cycle.

At block 1316, the wireless communication device determines whether there are additional decoding stages for which a path metric update should be completed. If there are additional decoding stages (Y branch of 1316), the wireless communication device may begin the next cycle at block 1306 and repeat the pipeline processing of multiple decoding stages at blocks 1308-1316. For example, the polar code list pipelining circuitry 1244 together with the polar code list decoding circuitry 1242 shown and described in reference to FIG. 12 may repeat the polar code list pipeline processing until the path metric update for each decoding stage has been completed.

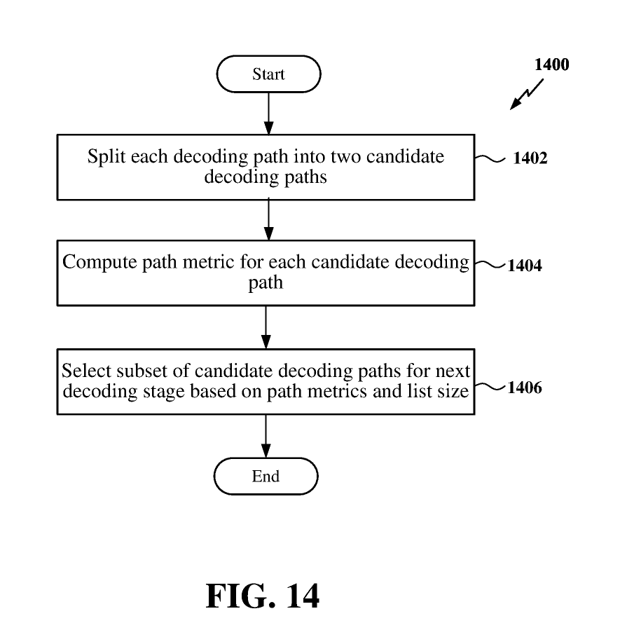

FIG. 14 is a flow chart illustrating an exemplary process 1400 for performing successive-cancellation polar code list decoding in accordance with some aspects of the present disclosure. As described below, some or all illustrated features may be omitted in a particular implementation within the scope of the present disclosure, and some illustrated features may not be required for implementation of all embodiments. In some examples, the process 1400 may be carried out by the wireless communication device illustrated in FIG. 12. In some examples, the process 1400 may be carried out by any suitable apparatus or means for carrying out the functions or algorithm described below.

The process 1400 illustrated in FIG. 14 may be performed at each decoding stage to select the decoding paths for the next decoding stage. At block 1402, the wireless communication device may split each initial decoding path of the decoding stage into two candidate decoding paths (e.g., the initial decoding path and a branch decoding path). At block 1404, the wireless communication device may compute the path metric for each of the candidate decoding paths. For example, the initial decoding paths may retain their path metric from the previous stage, while the branch decoding paths may each add a branch metric to their respective path metric from the previous stage. For example, the polar code list decoding circuitry 1242 shown and described above in reference to FIG. 12 may split each decoding path into two decoding paths and compute the path metric for each decoding path.

At block 1406, the wireless communication device may select a subset of the candidate decoding paths for the next decoding stage based on the path metrics and a list size. For example, with a list size of four, there will be eight candidate decoding paths after splitting the initial decoding paths at block 1402. From the eight candidate decoding paths, the four most likely candidate decoding paths (e.g., the four candidate decoding paths with the lowest path metrics) are selected for the next decoding stage. For example, the polar code list decoding circuitry 1242 shown and described in reference to FIG. 12 may compare path metrics and select decoding paths for the next decoding stage.

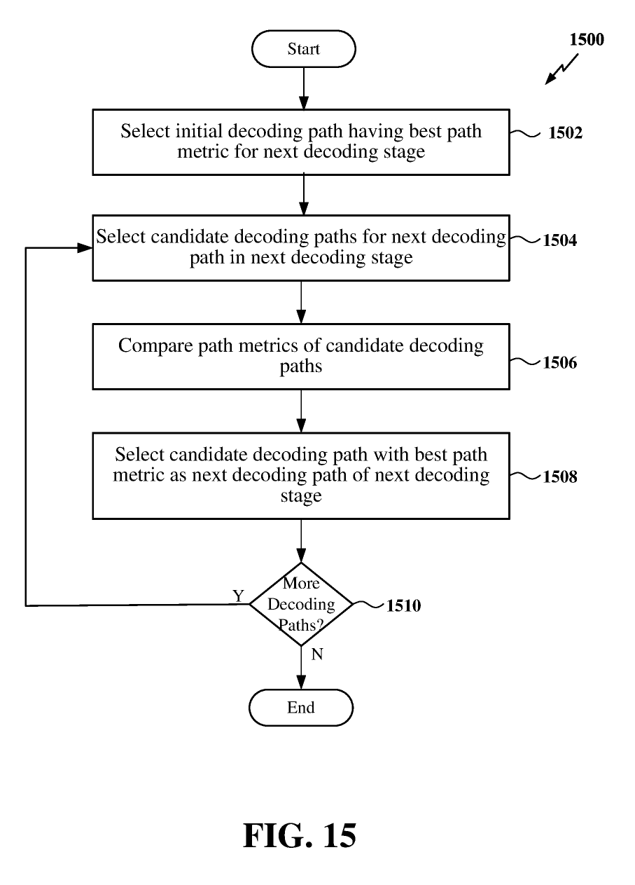

FIG. 15 is a flow chart illustrating an exemplary process 1500 for performing successive-cancellation polar code list decoding in accordance with some aspects of the present disclosure. As described below, some or all illustrated features may be omitted in a particular implementation within the scope of the present disclosure, and some illustrated features may not be required for implementation of all embodiments. In some examples, the process 1500 may be carried out by the wireless communication device illustrated in FIG. 12. In some examples, the process 1500 may be carried out by any suitable apparatus or means for carrying out the functions or algorithm described below.

The process 1500 illustrated in FIG. 15 may be performed at each decoding stage to select the decoding paths for the next decoding stage. At block 1502, the wireless communication device may select an initial decoding path having the best path metric in the current decoding stage for the next decoding stage. In some examples, the initial decoding path may be the same as the initial decoding path selected in the immediately prior decoding stage. For example, the polar code list decoding circuitry 1242 shown and described above in reference to FIG. 12 may select the initial decoding path.

At block 1504, the wireless communication device may select candidate decoding paths from unselected decoding paths in the current decoding stage for the next decoding path in the next decoding stage. In some examples, the candidate decoding paths include at least two best candidates from unselected decoding paths in the current decoding stage. In some examples, the best candidates are predefined based on the path metric rankings of the decoding paths and the fact that the path metric for a branch decoding path is based on the path metric of the root/initial decoding path with the addition of a branch metric. For example, the polar code list decoding circuitry 1242 shown and described above in reference to FIG. 12 may select the candidate decoding paths.

At block 1506, the wireless communication device may compare the path metrics of the candidate decoding paths, and at block 1508, select the candidate decoding path with the best path metric as the next decoding path in the next decoding stage. In some examples, the path metrics of the root decoding paths remain the same as the corresponding decoding path in the immediately prior decoding stage, and the path metrics for the branch decoding paths equal the sum of a branch metric and the path metric of the root decoding path of that branch decoding path. Thus, the wireless communication device may discern the path metrics of the candidate decoding paths and select the candidate decoding path with the best path metric. For example, the polar code list decoding circuitry 1242 shown and described above in reference to FIG. 12 may compare the path metrics and select the next decoding path.

At block 1510, the wireless communication device may determine whether there are additional decoding paths to be selected for the next decoding stage. If there are no more decoding paths to be selected for the next decoding stage (N branch of 1510), the process ends. However, if there are additional decoding paths to be selected (Y branch of 1510), the process repeats at block 1504, where the wireless communication device selects the candidate decoding paths for the next decoding path in the next decoding stage. In some examples, the wireless communication device may compare the number of selected decoding paths for the next decoding stage with the list size, and if the number of selected decoding paths equals the list size, the process may end. However, if the number of selected decoding paths is less than the list size, the process may repeat at block 1504 by selecting candidate decoding paths for the next decoding path in the next decoding stage from unselected decoding paths in the current decoding stage. For example, the polar code list decoding circuitry 1242 shown and described above in reference to FIG. 12 may determine whether there are additional decoding paths to be selected for the next decoding stage.

Several aspects of a wireless communication network have been presented with reference to an exemplary implementation. As those skilled in the art will readily appreciate, various aspects described throughout this disclosure may be extended to other telecommunication systems, network architectures and communication standards.

By way of example, various aspects may be implemented within other systems defined by 3GPP, such as Long-Term Evolution (LTE), the Evolved Packet System (EPS), the Universal Mobile Telecommunication System (UMTS), and/or the Global System for Mobile (GSM). Various aspects may also be extended to systems defined by the 3rd Generation Partnership Project 2 (3GPP2), such as CDMA2000 and/or Evolution-Data Optimized (EV-DO). Other examples may be implemented within systems employing IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in FIGS. 1-15 may be rearranged and/or combined into a single component, step, feature or function or embodied in several components, steps, or functions. Additional elements, components, steps, and/or functions may also be added without departing from novel features disclosed herein. The apparatus, devices, and/or components illustrated in FIGS. 1-15 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A method of pipelining polar code list decoding, the method comprising:
receiving a polar coded information transmission; and
performing successive-cancellation list decoding of the polar coded information transmission, wherein the successive-cancellation list decoding comprises:
during a cycle of a plurality of cycles:
comparing respective first path metrics for each of a plurality of first candidate decoding paths of a first decoding stage and selecting one of the plurality of first candidate decoding paths for a second decoding stage following the first decoding stage; and
comparing respective second path metrics for each of a plurality of second candidate decoding paths of the second decoding stage and selecting one of the plurality of second candidate decoding paths for a third decoding stage following the second decoding stage.

2. The method of claim 1, wherein the successive-cancellation list decoding further comprises:
during the cycle of the plurality of cycles:
comparing respective third path metrics for each of a plurality of third candidate decoding paths of the third decoding stage and selecting one of the plurality of third candidate decoding paths as a selected decoding path for a fourth decoding stage following the third decoding stage.

3. The method of claim 2, wherein the successive-cancellation list decoding further comprises:
during the cycle of the plurality of cycles:
selecting an initial decoding path for the fourth decoding stage, the initial decoding path having a best path metric for the fourth decoding stage;
wherein the selected decoding path selected from the plurality of third candidate decoding paths has a second best path metric for the fourth decoding stage.

4. The method of claim 3, wherein the successive-cancellation list decoding further comprises:
during an immediately prior cycle of the plurality of cycles:
selecting the initial decoding path for the third decoding stage, wherein the initial decoding path is the same for each of a plurality of decoding stages including the first decoding stage, the second decoding stage, the third decoding stage and the fourth decoding stage.

5. The method of claim 1, wherein the successive-cancellation list decoding further comprises:
during an initial cycle of the plurality of cycles:
selecting an initial decoding path for the second decoding stage, the initial decoding path having a best path metric for the second decoding stage; and
comparing respective initial path metrics for each of a plurality of initial decoding paths of the first decoding stage and selecting one of the plurality of initial decoding paths as a second selected decoding path for the second decoding stage following the first decoding stage, the second selected decoding path having a second best path metric for the second decoding stage.

6. The method of claim 5, wherein comparing respective first path metrics for each of the plurality of first candidate decoding paths of the first decoding stage and selecting one of the plurality of first candidate decoding paths for the second decoding stage following the first decoding stage further comprises:
utilizing unselected ones of the plurality of initial decoding paths in the plurality of first candidate decoding paths to select a third selected decoding path from the plurality of first candidate decoding paths for the second decoding stage, the third selected decoding path having a third best path metric for the second decoding stage.

7. The method of claim 1, further comprising:
at each decoding stage of a plurality of decoding stages:
splitting each of a plurality of current decoding paths into two additional decoding paths to produce a plurality of decoding paths;
computing a respective path metric for each of the plurality of decoding paths; and
selecting a subset of the plurality of decoding paths for a next decoding stage based on the respective path metrics of each of the plurality of decoding paths;
wherein the subset of the plurality of decoding paths is selected based on a list size.

8. The method of claim 7, further comprising:
at the first decoding stage of the plurality of decoding stages:
selecting the subset of the plurality of decoding paths for the second decoding stage by:
selecting the plurality of first candidate decoding paths from the plurality of decoding paths;
comparing the respective first path metrics for each of the plurality of first candidate decoding paths; and
selecting one of the plurality of first candidate decoding paths for the second decoding stage based on the respective first path metrics.

9. The method of claim 8, wherein selecting the plurality of first candidate decoding paths from the plurality of decoding paths further comprises:
selecting at least two best candidates from unselected ones of the plurality of decoding paths as the plurality of first candidate decoding paths, wherein the at least two best candidates are predefined.

10. The method of claim 8, wherein selecting the plurality of first candidate decoding paths from the plurality of decoding paths further comprises:
selecting the plurality of first candidate decoding paths based on previously selected decoding paths from a previous decoding stage during one or more previous cycles of the plurality of cycles, wherein the previous decoding stage is immediately prior to the first decoding stage.

11. The method of claim 10, wherein the previously selected decoding paths have the best path metrics from the previous decoding stage.

12. The method of claim 8, wherein selecting the subset of the plurality of decoding paths for the second decoding stage further comprises:
selecting the subset of the plurality of decoding paths in order of path metric ranking starting with a best path metric.

13. The method of claim 7, wherein the polar coded information transmission comprises a plurality of data bits, and wherein each of the plurality of data bits corresponds to one of the plurality of decoding stages.

14. The method of claim 13, wherein performing successive-cancellation list decoding of the polar coded information transmission further comprises:
selecting a single most likely decoding path for the plurality of data bits by:
selecting one of the current decoding paths for a first one of the plurality of data bits; and
selecting one of the subset of the plurality of decoding paths for a second one of the plurality of data bits.

15. An apparatus configured for pipelining polar code list decoding, comprising:
a transceiver;
a memory; and
a processor communicatively coupled to the transceiver and the memory, the processor configured to:
receive a polar coded information transmission; and
perform successive-cancellation list decoding of the polar coded information transmission, wherein the successive-cancellation list decoding comprises:
during a cycle of a plurality of cycles:
compare respective first path metrics for each of a plurality of first candidate decoding paths of a first decoding stage and selecting one of the plurality of first candidate decoding paths for a second decoding stage following the first decoding stage; and
compare respective second path metrics for each of a plurality of second candidate decoding paths of the second decoding stage and selecting one of the plurality of second candidate decoding paths for a third decoding stage following the second decoding stage.

16. The apparatus of claim 15, wherein the processor is further configured to:
during the cycle of the plurality of cycles:
comparing respective third path metrics for each of a plurality of third candidate decoding paths of the third decoding stage and selecting one of the plurality of third candidate decoding paths as a selected decoding path for a fourth decoding stage following the third decoding stage.

17. The apparatus of claim 16, wherein the processor is further configured to:
during the cycle of the plurality of cycles:
selecting an initial decoding path for the fourth decoding stage, the initial decoding path having a best path metric for the fourth decoding stage;
wherein the selected decoding path selected from the plurality of third candidate decoding paths has a second best path metric for the fourth decoding stage.

18. An apparatus configured for pipelining polar code list decoding, comprising:
means for receiving a polar coded information transmission; and
means for performing successive-cancellation list decoding of the polar coded information transmission, wherein the means for performing successive-cancellation list decoding comprises:
during a cycle of a plurality of cycles:
means for comparing respective first path metrics for each of a plurality of first candidate decoding paths of a first decoding stage and selecting one of the plurality of first candidate decoding paths for a second decoding stage following the first decoding stage; and
means for comparing respective second path metrics for each of a plurality of second candidate decoding paths of the second decoding stage and selecting one of the plurality of second candidate decoding paths for a third decoding stage following the second decoding stage.

19. The apparatus of claim 18, further comprising:
during the cycle of the plurality of cycles:
means for comparing respective third path metrics for each of a plurality of third candidate decoding paths of the third decoding stage and selecting one of the plurality of third candidate decoding paths as a selected decoding path for a fourth decoding stage following the third decoding stage.

20. The apparatus of claim 19, further comprising:
during the cycle of the plurality of cycles:
means for selecting an initial decoding path for the fourth decoding stage, the initial decoding path having a best path metric for the fourth decoding stage;
wherein the selected decoding path selected from the plurality of third candidate decoding paths has a second best path metric for the fourth decoding stage.
